(19) United States
(12) Patent Application Publication
(10) Pub. No.: US 2024/0047561 A1
(43) Pub. Date: Feb. 8, 2024

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Ta-Chun LIN, Hsinchu (TW); Ming-Che CHEN, Hsinchu City (TW); Chun-Jun LIN, Hsinchu City (TW); Kuo-Hua PAN, Hsinchu City (TW); Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 17/882,047

(22) Filed: Aug. 5, 2022

(51) Int. Cl. H01L 29/66; H01L 29/78; H01L 29/08

(52) U.S. Cl. CPC H01L 29/66795; H01L 29/7851; H01L 29/0847

(57) ABSTRACT

A method includes forming a semiconductor fin over a substrate; forming isolation structures laterally surrounding the semiconductor fin; forming a gate structure over the semiconductor fin; forming a first spacer layer and a second spacer layer over the gate structure and the semiconductor fin; etching back the second spacer layer, such that a top surface of the second spacer layer is lower than a top surface of the first spacer layer; after etching back the second spacer layer, forming a third spacer layer over the first spacer layer and the second spacer layer; etching the first, second, and third spacer layers and the semiconductor fin to form recesses; and forming epitaxial source/drain structures in the recesses.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 9E illustrate a method for manufacturing a semiconductor device at various stages in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

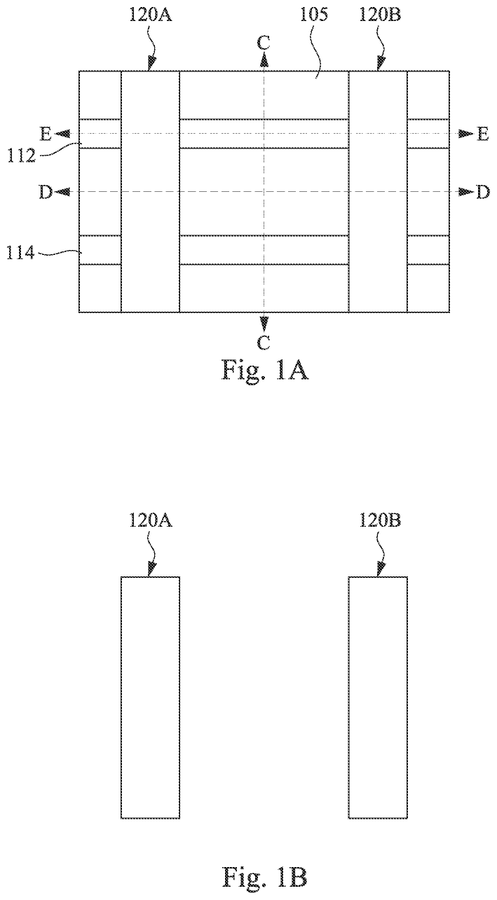

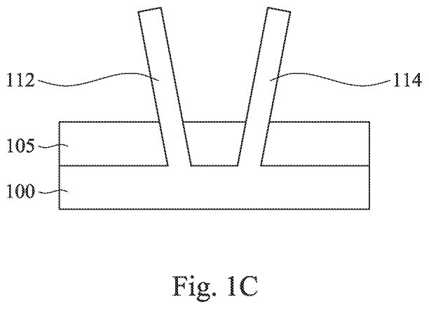

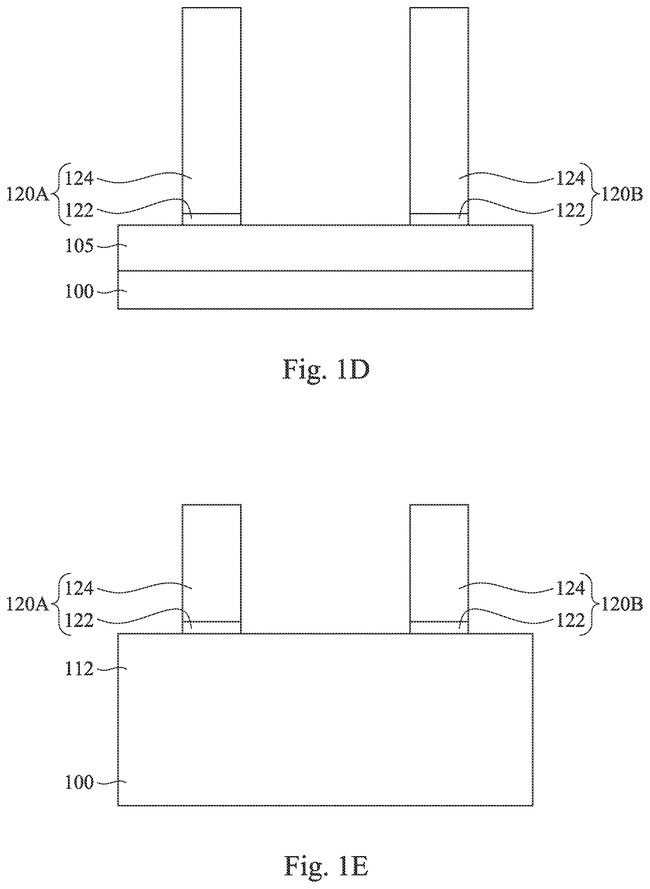

FIGS. 1A to 9E illustrate a method for manufacturing a semiconductor device at various stages in accordance with some embodiments of the present disclosure.

Reference is made to FIGS. 1A to 1E, in which FIG. 1A is a top view of a semiconductor device below a fin top, FIG. 1B is a top view of a semiconductor device above a fin top, FIG. 1C is a cross-sectional view along line C-C of FIG. 1A, FIG. 1D is cross-sectional view along line D-D of FIG. 1A, and FIG. 1E is cross-sectional view along line E-E of FIG. 1A. In greater details, FIG. 1A is a top view (or plane view) below top surfaces of semiconductor fins (e.g., fins 112 and 114), and FIG. 1B is a top view (or plane view) above top surfaces of semiconductor fins (e.g., fins 112 and 114).

Shown there is a substrate 100 (see FIGS. 1C to 1E). The substrate 100 may be a semiconductor substrate, such as a bulk semiconductor, a semiconductor-on-insulator (SOI) substrate, or the like. The substrate 100 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Semiconductor fins 112 and 114 are formed over the substrate 100. The semiconductor fins 112 and 114 may be formed by, for example, forming a mask layer over the substrate 100, in which the mask layer may include openings that expose portions of the substrate 100. The exposed substrate 100 is then etched through the openings of the mask layer, forming trenches in the substrate 100. A portion of the substrate 100 between neighboring trenches can be referred to as a semiconductor fin.

Isolation structures 105 may be formed over the substrate 100 and laterally surrounding bottom portions of the semiconductor fins 112 and 114. The isolation structures 105 can be referred to as shallow trench isolation (STI) structures. The isolation structures 105 can be formed by, for example depositing a dielectric material blanket over the substrate 100 and overfilling the spaces between the semiconductor fins 112 and 114, performing a planarization process such as chemical mechanical polish (CMP) to remove excess dielectric material until the top surfaces of the semiconductor fins 112 and 114 are exposed. Afterward, the dielectric material is recessed, for example, through an etching operation, in which diluted HF, SiCoNi (including HF and NH₃), or the like, may be used as the etchant. After recessing the isolation structures 105, top portions of the semiconductor fins 112 and 114 are higher than the top surfaces of the isolation structures 105, and hence top portions of the semiconductor fins 112 and 114 protrude above the isolation structures 105.

In some embodiments, the isolation structures 105 are made of silicon oxide, silicon nitride, silicon oxynitride, fluoride-doped silicate glass (FSG), or other low-K dielectric materials. In some embodiments, the isolation dielectric 160 may be formed using a high-density-plasma (HDP) chemical vapor deposition (CVD) process, using silane (SiH₄) and oxygen (O₂) as reacting precursors. In some other embodiments, the isolation structures 105 may be formed using a sub-atmospheric CVD (SACVD) process or high aspect-ratio process (HARP), in which process gases may include tetraethylorthosilicate (TEOS) and ozone (O₃). In yet other embodiments, the isolation structures 105 may be formed using a spin-on-dielectric (SOD) process, such as hydrogen silsesquioxane (HSQ) or methyl silsesquioxane (MSQ). Other processes and materials may be used. In some embodiments, the isolation structures 105 can have a multi-layer structure, for example, a thermal oxide liner layer with silicon nitride formed over the liner. Thereafter, a thermal annealing may be optionally performed to the isolation structures 105.

In FIG. 1C, in some embodiments, during the thermal annealing performed to the isolation structures 105, fin bending may occur due to different amount of oxide on opposite sides of each of the semiconductor fins 112 and 114, which cause an outward bending of the semiconductor fins 112 and 114. As a result, the semiconductor fins 112 and 114 may bend outwardly, and the trench between the semiconductor fins 112 and 114 may include a tapered profile. For example, a width of the trench between the semiconductor fins 112 and 114 may increase as a distance from the substrate 100 increases. In some other embodiments, the fin bending may not occur, and thus the semiconductor fins 112 and 114 may be substantially parallel to each other.

Dummy gate structures 120A and 120B are formed over the substrate 100 and crossing the semiconductor fins 112 and 114. In some embodiments, each of the dummy gate structures 120A and 120B includes a gate dielectric layer 122 and a gate electrode 124 over the gate dielectric layer 122. The dummy gate structures 120A and 120B may be formed by, for example, depositing a gate dielectric material blanket over the substrate 100, depositing a gate electrode material over the gate dielectric material, and then patterning the gate dielectric material and the gate electrode material.

In some embodiments, the gate dielectric layer 122 is an oxide layer, such as silicon oxide. In some embodiments, the gate dielectric layer 122 is made of high-k dielectric materials, such as metal oxides, transition metal-oxides, or the like. Examples of the high-k dielectric material include, but are not limited to, hafnium oxide (HfO₂), hafnium silicon oxide (HfSiO), hafnium tantalum oxide (HfTaO), hafnium titanium oxide (HfTiO), hafnium zirconium oxide (HfZrO), zirconium oxide, titanium oxide, aluminum oxide, hafnium dioxide-alumina (HfO₂—Al₂O₃) alloy, or other applicable dielectric materials. The gate dielectric layer 122 may be formed by a deposition processes, such as chemical vapor deposition (CVD), physical vapor deposition (PVD), atomic layer deposition (ALD), plasma enhanced CVD (PECVD) or other suitable techniques.

In some embodiments, the gate electrode 124 may include polycrystalline-silicon (poly-Si), poly-crystalline silicon-germanium (poly-SiGe), metallic nitrides, metallic silicides, metallic oxides, or metals. In some embodiments, the gate electrode 124 includes a metal-containing material such as TiN, TaN, TaC, Co, Ru, Al, combinations thereof, or multi-layers thereof. The gate electrode 124 may be deposited by CVD, physical vapor deposition (PVD), sputter deposition, or other techniques suitable for depositing conductive materials.

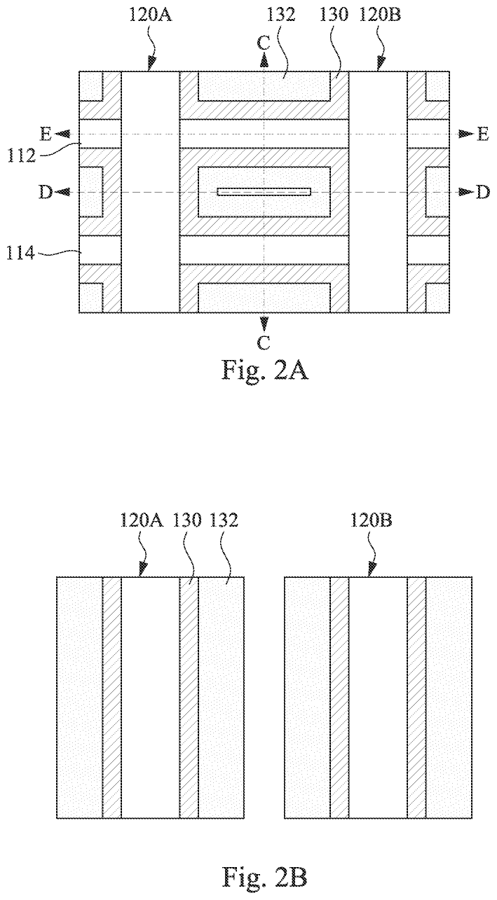

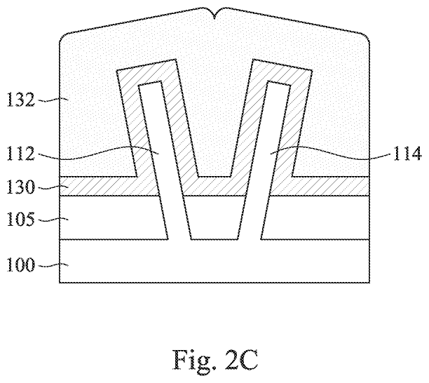

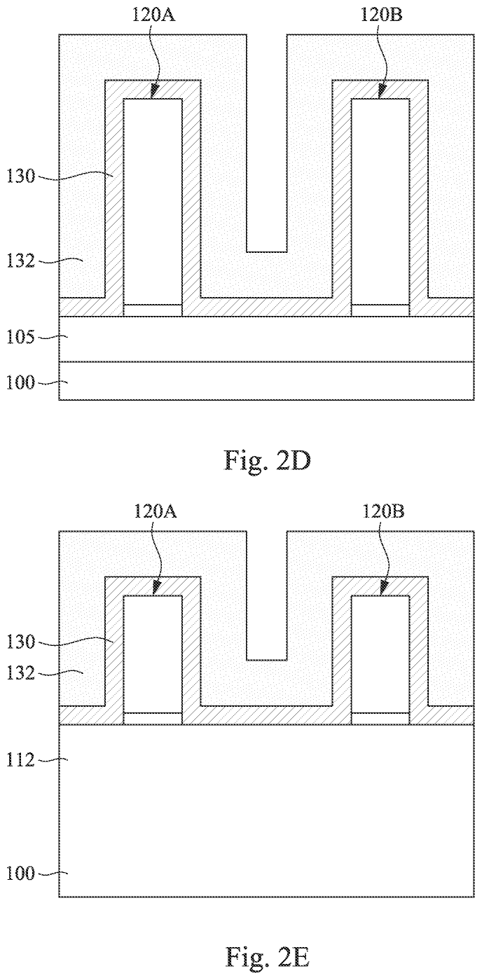

Reference is made to FIGS. 2A to 2E, in which FIG. 2A is a top view of a semiconductor device below a fin top, FIG. 2B is a top view of a semiconductor device above a fin top, FIG. 2C is a cross-sectional view along line C-C of FIG. 2A, FIG. 2D is cross-sectional view along line D-D of FIG. 2A, and FIG. 2E is cross-sectional view along line E-E of FIG. 2A. In greater details, FIG. 2A is a top view (or plane view) below top surfaces of semiconductor fins (e.g., fins 112 and 114), and FIG. 2B is a top view (or plane view) above top surfaces of semiconductor fins (e.g., fins 112 and 114).

A first spacer layer 130 is deposited over the substrate 100 and lining the structures formed over the substrate 100. In greater details, the first spacer layer 130 is formed extending along surfaces of the isolation structures 105, surfaces of the semiconductor fins 112 and 114, and surfaces the dummy gate structures 120A and 120B. In some embodiments, the first spacer layer 130 may be deposited via a conformal manner, such as using chemical vapor deposition (CVD) process or an atomic layer deposition (ALD) process. In some embodiments, the first spacer layer 130 may include silicon oxide, silicon nitride, silicon oxynitride, silicon carbide, silicon carbonitride, silicon oxycarbonitride, silicon oxycarbide, porous dielectric materials, hydrogen doped silicon oxycarbide (SiOC:H), low-k dielectric materials or other suitable dielectric material.

A second spacer layer 132 is then deposited over the first spacer layer 130. In some embodiments, the second spacer layer 132 may be deposited via a conformal manner, such as using chemical vapor deposition (CVD) process or an atomic layer deposition (ALD) process. However, the second spacer layer 132 may be deposited thick enough to overfill the trench between the semiconductor fins 112 and 114, as shown in FIG. 2C. That is, an entirety of the trench between the semiconductor fins 112 and 114 is filled with the first spacer layer 130 and the second spacer layer 132 after the deposition of the second spacer layer 132 is completed. In some embodiments, the second spacer layer 132 may be thicker than the first spacer layer 130, so as to ensure that the trench between the semiconductor fins 112 and 114 is overfilled. In some embodiments, the second spacer layer 132 may include silicon oxide, silicon nitride, silicon oxynitride, silicon carbide, silicon carbonitride, silicon oxycarbonitride, silicon oxycarbide, porous dielectric materials, hydrogen doped silicon oxycarbide (SiOC:H), low-k dielectric materials or other suitable dielectric material. In some embodiments, the first spacer layer 130 and the second spacer layer 132 are made of different dielectric materials. In some embodiments, the dielectric constant of the second spacer layer 132 is lower than the dielectric constant of the first spacer layer 130.

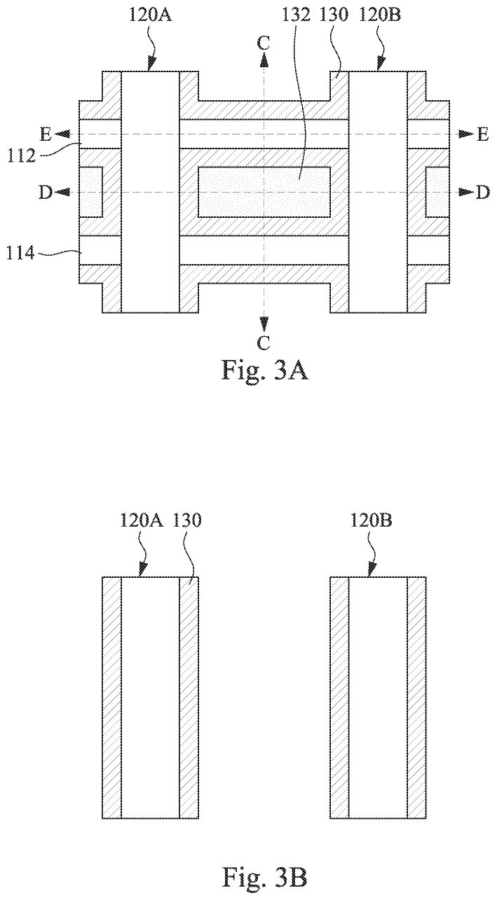

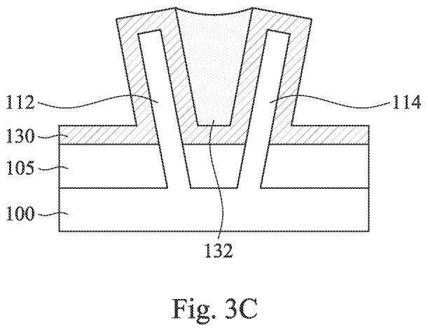

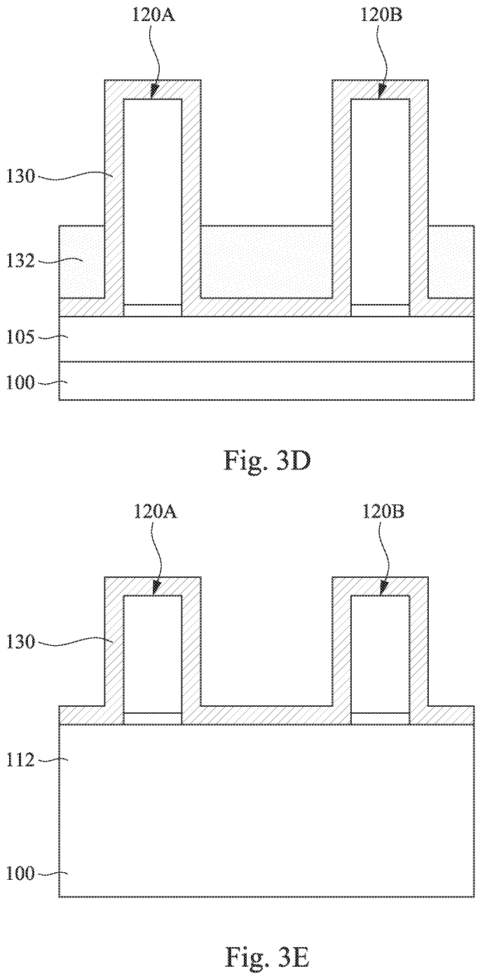

Reference is made to FIGS. 3A to 3E, in which FIG. 3A is a top view of a semiconductor device below a fin top, FIG. 3B is a top view of a semiconductor device above a fin top, FIG. 3C is a cross-sectional view along line C-C of FIG. 3A, FIG. 3D is cross-sectional view along line D-D of FIG. 3A, and FIG. 3E is cross-sectional view along line E-E of FIG. 3A. In greater details, FIG. 3A is a top view (or plane view) below top surfaces of semiconductor fins (e.g., fins 112 and 114), and FIG. 3B is a top view (or plane view) above top surfaces of semiconductor fins (e.g., fins 112 and 114).

An etching back process is performed to remove portions of the second spacer layer 132. In some embodiments where the first spacer layer 130 and the second spacer layer 132 are made of different dielectric materials, the first spacer layer 130 may include a higher etching resistance to the etching back process than the second spacer layer 132, such that the first spacer layer 130 may be kept substantially intact after the etching back process is completed.

In the top view of FIG. 3A and the cross-sectional view of FIG. 3C, it can be seen that portions of the second spacer layer 132 outside the space laterally between the semiconductor fins 112 and 114 are removed, while portions of the second spacer layer 132 laterally between the semiconductor fins 112 and 114 remain after the etching process is completed. This is because it is hard for the etching process to etch the portions of the second spacer layer 132 is a small space, such as the space laterally between the semiconductor fins 112 and 114.

In the cross-sectional view of FIG. 3C, it can be seen that portions of the second spacer layer 132 are removed to expose the first spacer layer 130. With respect to the semiconductor fin 112, the semiconductor fin 112 may include a first sidewall distal to the semiconductor fin 114 and a second sidewall facing the semiconductor fin 114. Portions of the second spacer layer 132 are removed from portions of the first spacer layer 130 that are above the top surface of the semiconductor fin 112 and on the first sidewall of the semiconductor fin 112. Accordingly, the portions of the first spacer layer 130 that are above the top surface of the semiconductor fin 112 and on the first sidewall of the semiconductor fin 112 are exposed after the etching back process is completed. However, the portion of the first spacer layer 130 on the second sidewall of the semiconductor fin 112 remains covered by the second spacer layer 132 after the etching back process is completed.

With respect to the semiconductor fin 114, the semiconductor fin 114 may include a first sidewall distal to the semiconductor fin 112 and a second sidewall facing the semiconductor fin 112. Similarly, portions of the second spacer layer 132 are removed from portions of the first spacer layer 130 that are above the top surface of the semiconductor fin 114 and on the first sidewall of the semiconductor fin 114. Accordingly, the portions of the first spacer layer 130 that are above the top surface of the semiconductor fin 114 and on the first sidewall of the semiconductor fin 114 are exposed after the etching back process is completed. However, the portion of the first spacer layer 130 on the second sidewall of the semiconductor fin 114 remains covered by the second spacer layer 132 after the etching back process is completed.

Stated another, in FIG. 3C, only the portion of the first spacer layer 130, which is in the space laterally between the semiconductor fins 112 and 114, remains covered by the second spacer layer 132 after the etching back process is completed. In some embodiments, the topmost end of the first spacer layer 130 is higher than the topmost end of the second spacer layer 132.

In the cross-sectional view of FIG. 3D, it can be seen that portions of the second spacer layer 132 are removed from the top portions of the first spacer layer 130, such that top portions of the first spacer layer 130 are exposed after the etching back process is completed. Accordingly, bottom portions of the first spacer layer 130 remain covered by the second spacer layer 132 after the etching back process is completed. In some embodiments, top surfaces of the remaining portions of the second spacer layer 132 are lower than top surfaces of the dummy gate structures 120A and 120B. In some embodiments, top surfaces of the remaining portions of the second spacer layer 132 are lower than topmost ends of the first spacer layer 130. In some embodiments, the second spacer layer 132 is changed from a U-shape cross-section (see FIG. 2D) to a rectangular cross-section.

In the cross-sectional view of FIG. 3E, it can be seen that portions of the second spacer layer 132 are removed, such that portions of the first spacer layer 130 that are vertically above the semiconductor fin 112 (or 114) are exposed. Stated another way, portions of the second spacer layer 132 that are vertically above the semiconductor fin 112 (or 114) are completely removed. Accordingly, in some embodiments, no second spacer layer 132 remains in the cross-sectional view of FIG. 3E after the etching back process is completed.

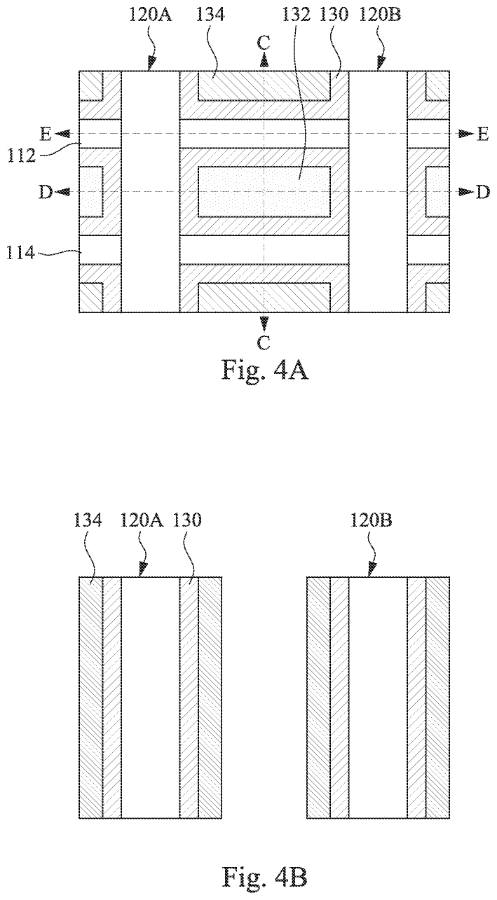

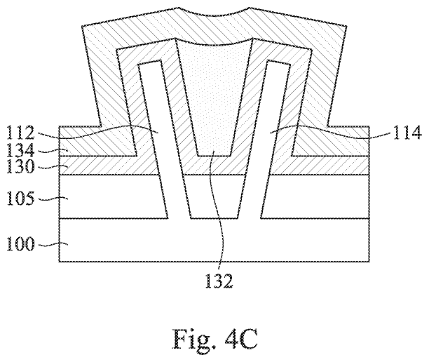

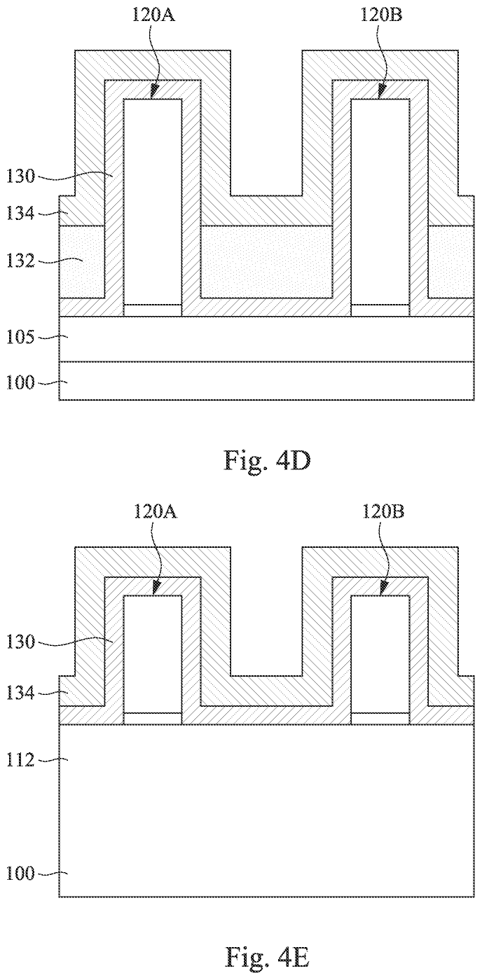

Reference is made to FIGS. 4A to 4E, in which FIG. 4A is a top view of a semiconductor device below a fin top, FIG. 4B is a top view of a semiconductor device above a fin top, FIG. 4C is a cross-sectional view along line C-C of FIG. 4A, FIG. 4D is cross-sectional view along line D-D of FIG. 4A, and FIG. 4E is cross-sectional view along line E-E of FIG. 4A. In greater details, FIG. 4A is a top view (or plane view) below top surfaces of semiconductor fins (e.g., fins 112 and 114), and FIG. 4B is a top view (or plane view) above top surfaces of semiconductor fins (e.g., fins 112 and 114).

After the etching process performed to the second spacer layer 132 is completed, a third spacer layer 134 is deposited over the first spacer layer 130 and the second spacer layer 132. In some embodiments, the third spacer layer 134 may be deposited via a conformal manner, such as using chemical vapor deposition (CVD) process or an atomic layer deposition (ALD) process. In some embodiments, the third spacer layer 134 may include silicon oxide, silicon nitride, silicon oxynitride, silicon carbide, silicon carbonitride, silicon oxycarbonitride, silicon oxycarbide, porous dielectric materials, hydrogen doped silicon oxycarbide (SiOC:H), low-k dielectric materials or other suitable dielectric material. In some embodiments, the first spacer layer 130, the second spacer layer 132, and the third spacer layer 134 are made of different dielectric materials. In some embodiments, the dielectric constant of the second spacer layer 132 is lower than the dielectric constant of the third spacer layer 134.

In the cross-sectional view of FIG. 4C, the third spacer layer 134 may be in contact with the first spacer layer 130 and the second spacer layer 132. In greater details, the third spacer layer 134 may be in contact with top surface of the remaining portion of the second spacer layer 132 that is laterally between the semiconductor fins 112 and 114. The third spacer layer 134 may be in contact with portions of the first spacer layer 130 that are uncovered by the second spacer layer 132.

In the cross-sectional view of FIG. 4D, the third spacer layer 134 may be in contact with the first spacer layer 130 and the second spacer layer 132. In greater details, the third spacer layer 134 may be in contact with top surface of the remaining portion of the second spacer layer 132. The third spacer layer 134 may be in contact with top portions of the first spacer layer 130, and may be separated from the bottom portions of the first spacer layer 130 by the second spacer layer 132. In some embodiments, the first spacer layer 130 and the third spacer layer 134 both include a U-shape cross-section, while the remaining portion of the second spacer layer 132 has a rectangular cross-section.

In the cross-sectional view of FIG. 4E, the third spacer layer 134 may line the first spacer layer 130. Because portions of the second spacer layer 132 is removed from the cross-sectional view of FIG. 4E, the third spacer layer 134 may be in contact with vertical portions of the first spacer layer 130 and lateral portions of the first spacer layer 130.

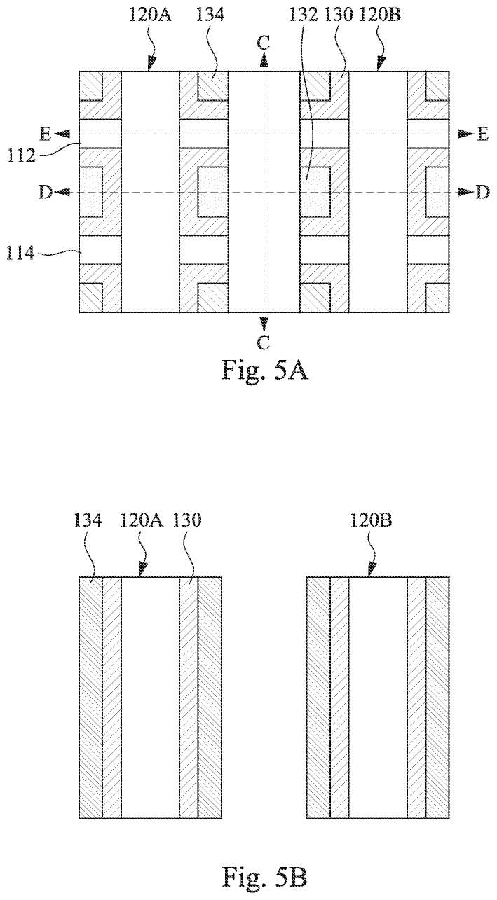

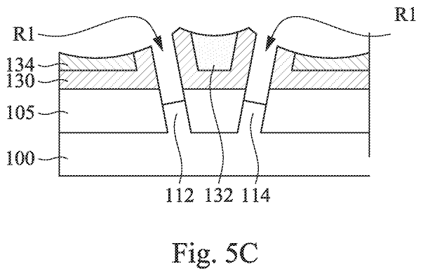

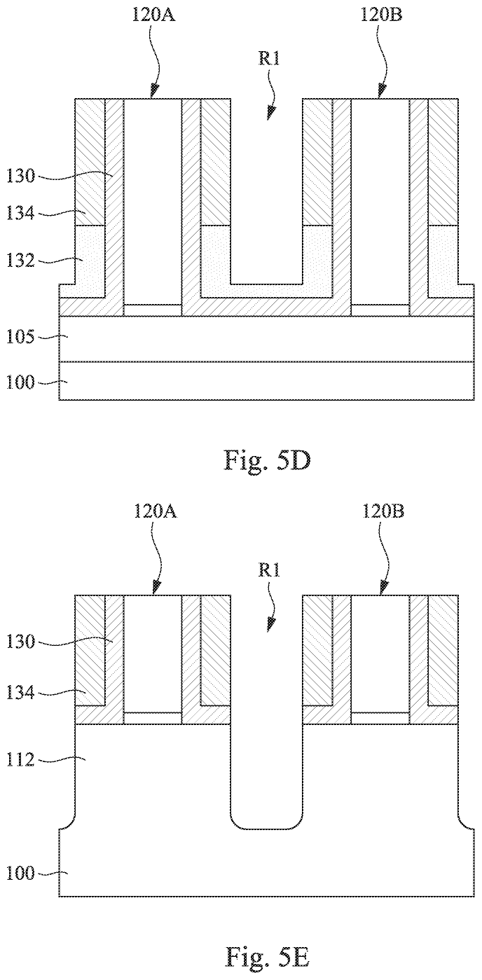

Reference is made to FIGS. 5A to 5E, in which FIG. 5A is a top view of a semiconductor device below a fin top, FIG. 5B is a top view of a semiconductor device above a fin top, FIG. 5C is a cross-sectional view along line C-C of FIG. 5A, FIG. 5D is cross-sectional view along line D-D of FIG. 5A, and FIG. 5E is cross-sectional view along line E-E of FIG. 5A. In greater details, FIG. 5A is a top view (or plane view) below top surfaces of semiconductor fins (e.g., fins 112 and 114), and FIG. 5B is a top view (or plane view) above top surfaces of semiconductor fins (e.g., fins 112 and 114).

An etching process is performed to remove portions of the first spacer layer 130, the second spacer layer 132, and the third spacer layer 134, and portions of the semiconductor fins 112 and 114. In greater details, the etching process may include a first etch for etching the first spacer layer 130, the second spacer layer 132, and the third spacer layer 134, and a second etching for etching the semiconductor fins 112 and 114.

In some embodiments, the first etch of the etching process may include an anisotropic etch, such as a dry etch. The first etch is performed to remove horizontal portions of the first spacer layer 130, the second spacer layer 132, and the third spacer layer 134, so as to expose semiconductor fins 112 and 114. Afterwards, the second etch of the etching process may remove portions of the exposed semiconductor fins 112 and 114 to form recesses R1 in the semiconductor fins 112 and 114.

In the cross-sectional view of FIG. 5C, portions of the first spacer layer 130, the second spacer layer 132, and the third spacer layer 134 are removed, and then portions of the semiconductor fins 112 and 114 are removed to form the recesses R1.

In the cross-sectional view of FIG. 5D, portions of the first spacer layer 130, the second spacer layer 132, and the third spacer layer 134 are removed. In greater details, the second spacer layer 132 is etched, such that the second spacer layer 132 is changed from a rectangular cross-section (see FIG. 4D) to a U-shape cross-section. In some embodiments, the second spacer layer 132 may act as a protective layer to protect bottom portions of the first spacer layer 130 from being etched.

In the cross-sectional view of FIG. 5E, the horizontal portions of the first spacer layer 130 and the third spacer layer 134 are removed, and the semiconductor fin 112 (or 114) is etched to form the recesses R1.

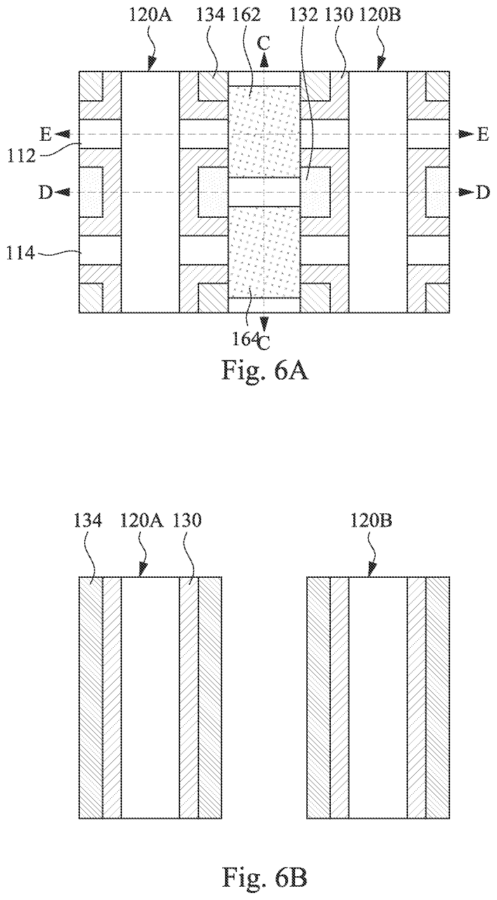

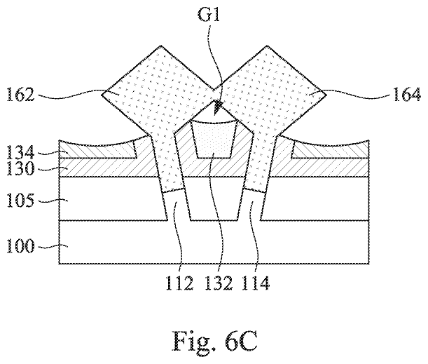

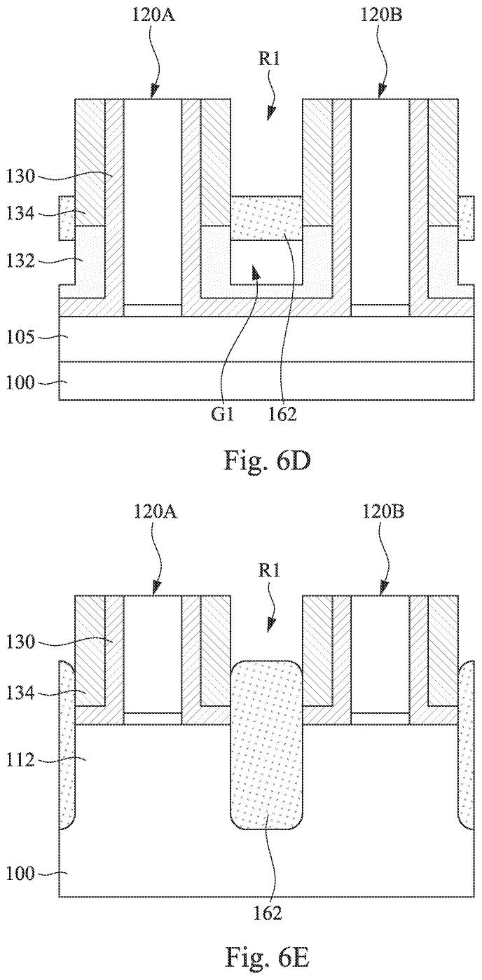

Reference is made to FIGS. 6A to 6E, in which FIG. 6A is a top view of a semiconductor device below a fin top, FIG. 6B is a top view of a semiconductor device above a fin top, FIG. 6C is a cross-sectional view along line C-C of FIG. 6A, FIG. 6D is cross-sectional view along line D-D of FIG. 6A, and FIG. 6E is cross-sectional view along line E-E of FIG. 6A. In greater details, FIG. 6A is a top view (or plane view) below top surfaces of semiconductor fins (e.g., fins 112 and 114), and FIG. 6B is a top view (or plane view) above top surfaces of semiconductor fins (e.g., fins 112 and 114).

Epitaxial source/drain structures 142 and 144 are formed in the recesses R1 of the semiconductor fins 112 and 114, respectively. The epitaxy source/drain structures 162 are formed over the semiconductor fin 112, and the epitaxy source/drain structures 164 are formed over the semiconductor fin 114.

In greater details, as shown in the cross-sectional view of FIGS. 6D and 6E, the epitaxial source/drain structures 162 are formed on opposite sides of the dummy gate structure 120A (or 120B). Similarly, the epitaxial source/drain structures 164 may be formed on opposite sides of the dummy gate structure 120A (or 120B). Source/drain region(s) may refer to a source or a drain, individually or collectively dependent upon the context.

In the cross-sectional view of FIG. 6C, the epitaxial source/drain structures 162 and 164 may merge together. That is, the epitaxial source/drain structures 162 and 164 may be in contact with each other. In some embodiments, a gap G1 is formed under the epitaxial source/drain structures 162 and 164. In greater details, the gap G1 is defined by the epitaxial source/drain structures 162 and 164 and the second spacer layer 132. That is, top surface of the second spacer layer 132 may be exposed to the gap G1.

In the cross-sectional view of FIG. 6D, the source/drain structures 162 (or 164) may be in contact with the second spacer layer 132 and the third spacer layer 134. In some embodiments, the source/drain structures 162 (or 164) may be in contact with the interface between the second spacer layer 132 and the third spacer layer 134. In the cross-sectional view of FIG. 6D, the source/drain structures 162 (or 164) may be separated from the first spacer layer 130 by the second spacer layer 132 and the third spacer layer 134. Similarly, a gap G1 is formed under the source/drain structures 162. In greater details, the gap G1 is defined by the epitaxial source/drain structure 162 and the second spacer layer 132.

In the cross-sectional view of FIG. 6E, the source/drain structures 162 (or 164) may be in contact with the first spacer layer 130 and the third spacer layer 134. In some embodiments, the source/drain structures 162 (or 164) may be in contact with the interface between the first spacer layer 130 and the third spacer layer 134.

The epitaxial source/drain structures 162 and 164 may be formed using one or more epitaxy or epitaxial (epi) processes, such that Si features, SiGe features, silicon phosphate (SiP) features, silicon carbide (SiC) features and/or other suitable features can be formed in a crystalline state on the recessed portions of the semiconductor fins 112 and 114. In some embodiments, lattice constants of the epitaxial source/drain structures 162 and 164 are different from that of the semiconductor fins 112 and 114, so that the channel region between the epitaxial source/drain structures 162 and 164 can be strained or stressed by the epitaxial source/drain structures 162 and 164 to improve carrier mobility of the semiconductor device and enhance the device performance.

The epitaxy processes include CVD deposition techniques (e.g., vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor fins 162 and 164 (e.g., silicon, silicon germanium, silicon phosphate, or the like). The epitaxial source/drain structures 162 and 164 may be in-situ doped. The doping species include p-type dopants, such as boron or BF₂; n-type dopants, such as phosphorus or arsenic; and/or other suitable dopants including combinations thereof. If the epitaxial source/drain structures 162 and 164 are not in-situ doped, a second implantation process (i.e., a junction implant process) is performed to dope the epitaxial source/drain structures 162 and 164. One or more annealing processes may be performed to activate the epitaxial source/drain structures 162 and 164. The annealing processes include rapid thermal annealing (RTA) and/or laser annealing processes.

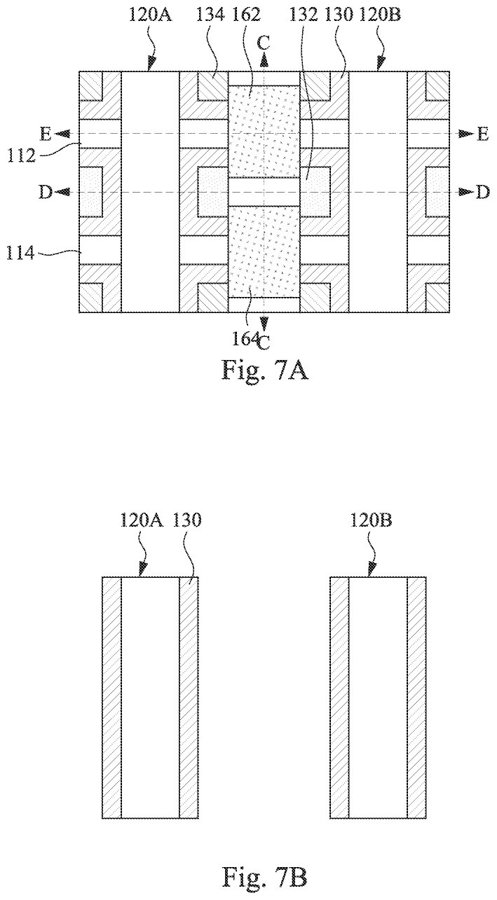

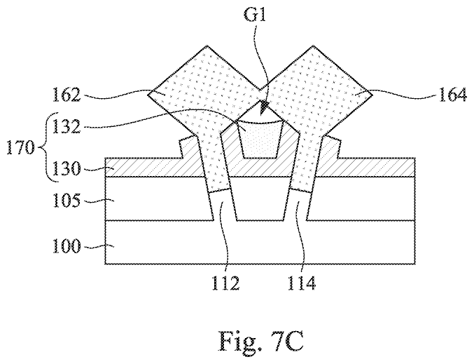

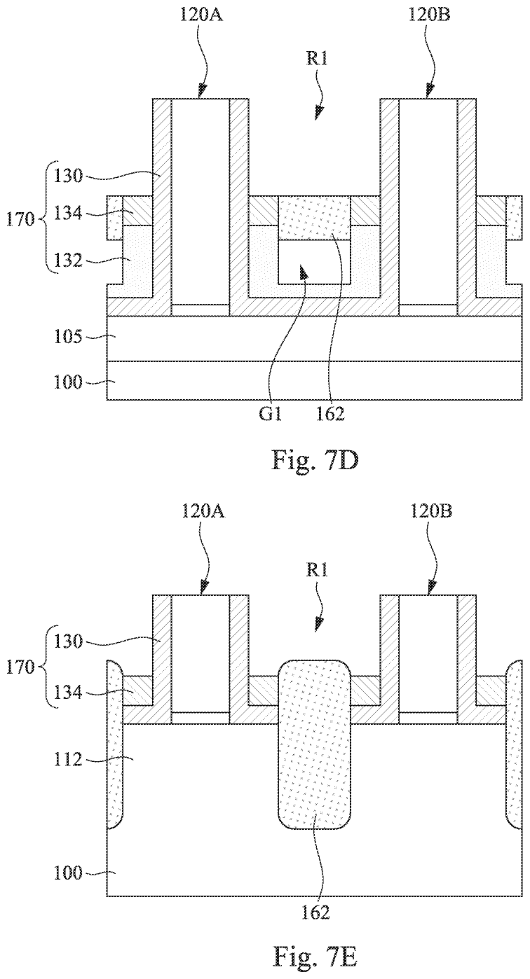

Reference is made to FIGS. 7A to 7E, in which FIG. 7A is a top view of a semiconductor device below a fin top, FIG. 7B is a top view of a semiconductor device above a fin top, FIG. 7C is a cross-sectional view along line C-C of FIG. 7A, FIG. 7D is cross-sectional view along line D-D of FIG. 7A, and FIG. 7E is cross-sectional view along line E-E of FIG. 7A. In greater details, FIG. 7A is a top view (or plane view) below top surfaces of semiconductor fins (e.g., fins 112 and 114), and FIG. 7B is a top view (or plane view) above top surfaces of semiconductor fins (e.g., fins 112 and 114).

After the epitaxial source/drain structures 162 and 164 are formed, an etching back process is performed to the third spacer layer 134, so as to lower top surfaces of the third spacer layer 134. In some embodiments where the first spacer layer 130 and the second spacer layer 132 are made of different materials than the third spacer layer 134, the first spacer layer 130 and the second spacer layer 132 may include higher etching resistance to the etching back process than the third spacer layer 134.

As shown in the cross-sectional view of FIG. 7C, the third spacer layer 130 is removed to expose the first spacer layer 130.

As shown in the cross-sectional view of FIG. 7D, the third spacer layer 130 is etched back, such that top surfaces of the third spacer layer 130 are lower than top surfaces of the first spacer layer 130.

As shown in the cross-sectional view of FIG. 7E, the third spacer layer 130 is etched back, such that top surfaces of the third spacer layer 130 are lower than top surfaces of the first spacer layer 130. Moreover, the top surfaces of the third spacer layer 130 are lower than top surfaces of the epitaxial source/drain structures 162 (or 164).

After the etching back process is completed, gate spacers 170 are formed. In some embodiments, each of the gate spacers 170 may include remaining portions of the first spacer layer 130, the second spacer layer 132, and the third spacer layer 134. In the cross-sectional view of FIG. 7D, the top portion of each gate spacer 170 is thinner than the bottom portion of each gate spacer 170. For example, the top portion of each gate spacer 170 include the first spacer layer 130 and the third spacer layer 134, while the bottom portion of each gate spacer 170 include the first spacer layer 130, the second spacer layer 132, and the third spacer layer 134.

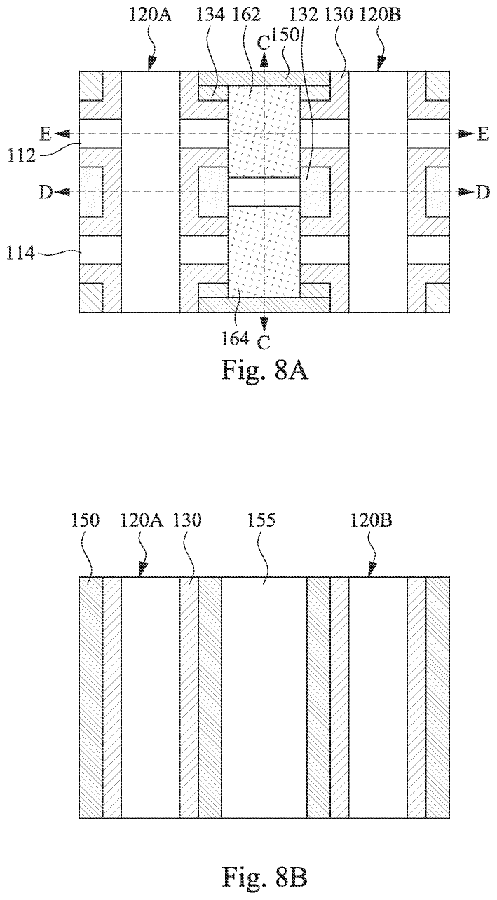

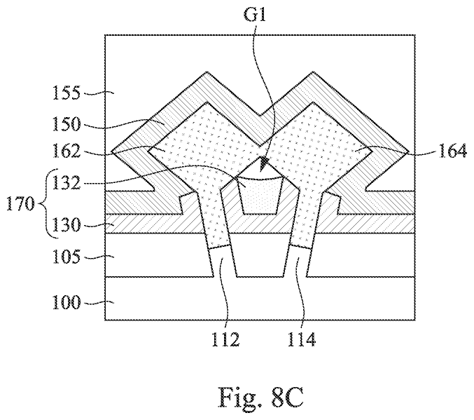

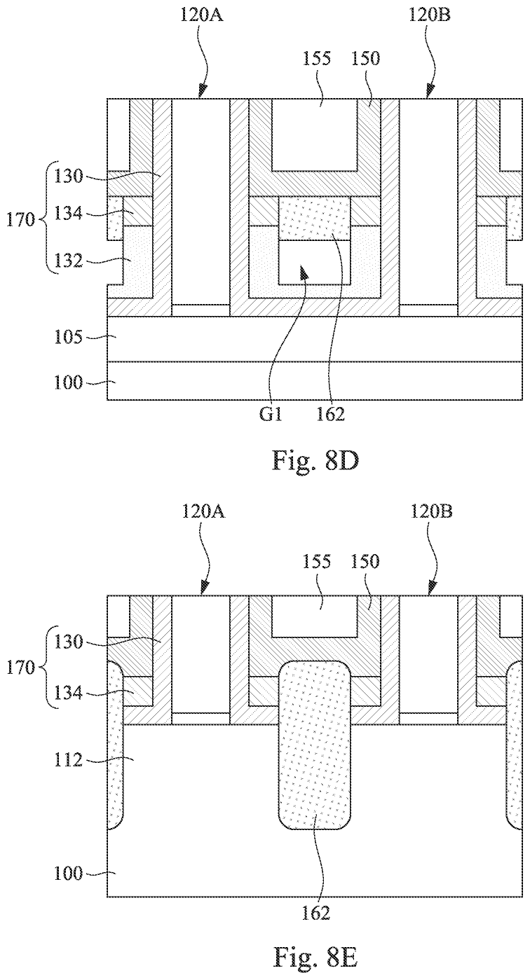

Reference is made to FIGS. 8A to 8E, in which FIG. 8A is a top view of a semiconductor device below a fin top, FIG. 8B is a top view of a semiconductor device above a fin top, FIG. 8C is a cross-sectional view along line C-C of FIG. 8A, FIG. 8D is cross-sectional view along line D-D of FIG. 8A, and FIG. 8E is cross-sectional view along line E-E of FIG. 8A. In greater details, FIG. 8A is a top view (or plane view) below top surfaces of semiconductor fins (e.g., fins 112 and 114), and FIG. 8B is a top view (or plane view) above top surfaces of semiconductor fins (e.g., fins 112 and 114).

Contact etch stop layer (CESL) 150 is formed over the epitaxial source/drain structures 162 and 164, and then an interlayer dielectric (ILD) layer 155 is formed over the CESL 150. Afterwards, a CMP process may be performed to remove excessive materials of the ILD layer 155 and the CESL 150 to expose the dummy gate structures 120A and 120B. The CMP process may planarize top surfaces of the ILD layer 155 and the CESL 150 with top surfaces of the dummy gate structures 120A and 120B.

In the cross-sectional view of FIG. 8C, the CESL 150 may extend along surfaces of the epitaxial source/drain structures 162 and 164, and may be in contact with the first spacer layer 130.

In the cross-sectional view of FIG. 8D, the CESL 150 may be in contact with the first spacer layer 130 and the third spacer layer 132. In greater details, the CESL 150 is in contact with sidewalls of the first spacer layer 130 and top surfaces of the third spacer layer 134. In some embodiments, the CESL 150 is separated from the second spacer layer 132 by the third spacer layer 134.

In the cross-sectional view of FIG. 8E, the CESL 150 may be in contact with the first spacer layer 130 and the third spacer layer 132. In greater details, the CESL 150 is in contact with sidewalls of the first spacer layer 130 and top surfaces of the third spacer layer 134. In some embodiments, the interface between the CESL 150 and the third spacer layer 134 may be lower than a topmost end of the epitaxial source/drain structure 162 (or 164).

The CESL 150 may be a dielectric layer including silicon nitride, silicon oxynitride or other suitable materials. The CESL 150 can be formed using, for example, plasma enhanced CVD, low pressure CVD, ALD or other suitable techniques. The ILD layer 155 may include a material different from the CESL 150. In some embodiments, the ILD layer 155 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 155 may be formed using, for example, CVD, ALD, spin-on-glass (SOG) or other suitable techniques.

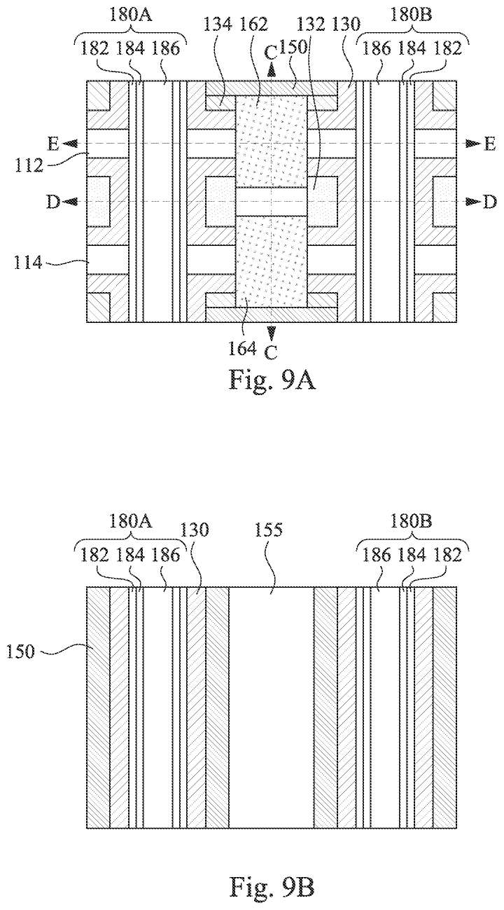

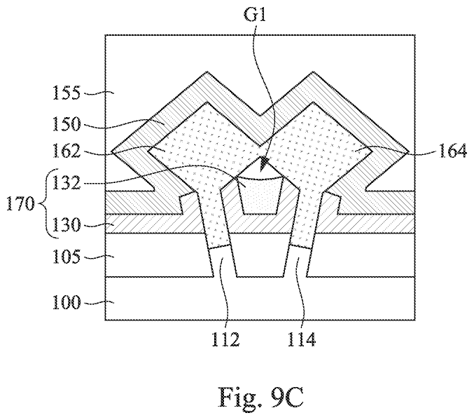

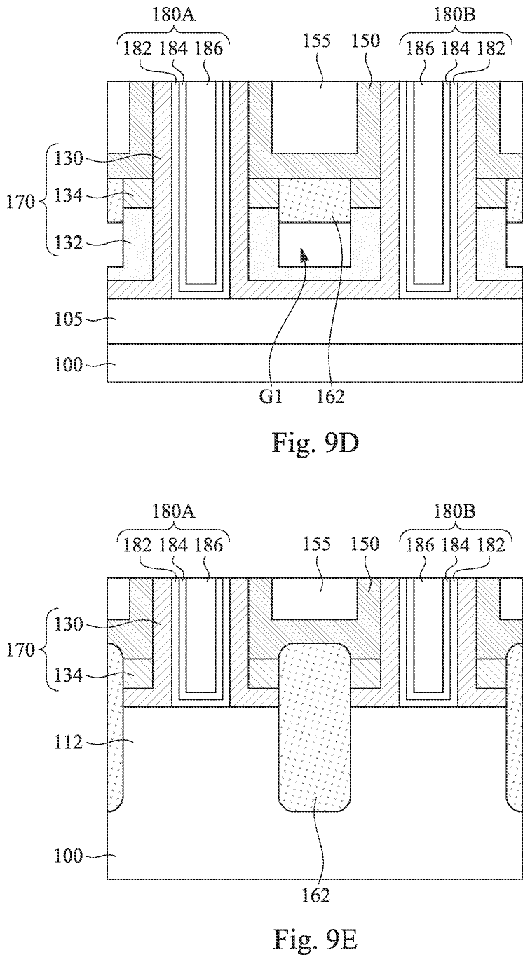

Reference is made to FIGS. 9A to 9E, in which FIG. 9A is a top view of a semiconductor device below a fin top, FIG. 9B is a top view of a semiconductor device above a fin top, FIG. 9C is a cross-sectional view along line C-C of FIG. 9A, FIG. 9D is cross-sectional view along line D-D of FIG. 9A, and FIG. 9E is cross-sectional view along line E-E of FIG. 9A. In greater details, FIG. 9A is a top view (or plane view) below top surfaces of semiconductor fins (e.g., fins 112 and 114), and FIG. 9B is a top view (or plane view) above top surfaces of semiconductor fins (e.g., fins 112 and 114).

The dummy gate structures 120A and 120B are replaced with the metal gate structures 180A and 180B. In some embodiments, the dummy gate structures 120A and 120B may be removed by suitable etching process, so as to form gate trenches between each pair of the gate spacers 170. Then, layers of the metal gate structures 180A and 180B are deposited in the gate trenches, followed by a CMP process to remove excess materials of the layers of the metal gate structures 180A and 180B until the ILD layer 155 is exposed. In some embodiments, each of the metal gate structures 180A and 180B may include a gate dielectric layer 182, a work function metal layer 184, and a gate electrode 186 over the work function metal layer 184.

In some embodiments, the gate dielectric layer 182 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 182 may be formed by CVD, ALD or any suitable method.

In some embodiments, the work function metal layer 184 may be made of a conductive material such as a single layer of TiN, TaN, TaAlC, TiC, TaC, Co, Al, TiAl, HfTi, TiSi, TaSi or TiAlC, or a multilayer of two or more of these materials. For the n-channel FET, one or more of TaN, TaAlC, TiN, TiC, Co, TiAl, HfTi, TiSi and TaSi is used as the work function metal layer 144, and for the p-channel FET, one or more of TiAlC, Al, TiAl, TaN, TaAlC, TiN, TiC and Co is used as the work function metal layer 184. The work function metal layer 184 may be formed by ALD, PVD, CVD, e-beam evaporation, or other suitable process.

In some embodiments, the gate electrode 186 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode 186 may be formed by CVD, ALD, electro-plating, or other suitable method.

Based on the above discussions, it can be seen that the present disclosure offers advantages. It is understood, however, that other embodiments may offer additional advantages, and not all advantages are necessarily disclosed herein, and that no particular advantage is required for all embodiments. Embodiments of the present disclosure provide a method for forming a gate spacer, which includes a first spacer layer, a second spacer layer, and a third spacer layer. The second spacer layer is etched back, such that the remaining second spacer layer is below fin top. As a result, the remaining second spacer layer may mitigate metal gate extrusion (MGEX) during forming a metal gate structure. The second spacer layer is formed with a low-k dielectric material, which in turn will reduce the device capacitance. Moreover, because the second spacer layer is etched back, top portions of the gate spacer may be thinned, the thinner gate spacer may improve the growth of source/drain epitaxy structures, which will improve the device performance.

In some embodiments of the present disclosure, a method includes forming a semiconductor fin over a substrate; forming isolation structures laterally surrounding the semiconductor fin; forming a gate structure over the semiconductor fin; forming a first spacer layer and a second spacer layer over the gate structure and the semiconductor fin; etching back the second spacer layer, such that a top surface of the second spacer layer is lower than a top surface of the first spacer layer; after etching back the second spacer layer, forming a third spacer layer over the first spacer layer and the second spacer layer; etching the first, second, and third spacer layers and the semiconductor fin to form recesses; and forming epitaxial source/drain structures in the recesses.

In some embodiments, the method further includes etching back the third spacer layer to expose sidewall of the first spacer layer after forming the epitaxial source/drain structures in the recesses.

In some embodiments, etching back the third spacer layer is performed such that a top surface of the third spacer layer is lower than a topmost end of one of the epitaxial source/drain structures.

In some embodiments, the method further includes forming a contact etch stop layer over the epitaxial source/drain structures, wherein the contact etch stop layer is in contact with the first and third spacer layers.

In some embodiments, the contact etch stop layer is separated from the second spacer layer by the third spacer layer.

In some embodiments, forming the second spacer layer is performed such that the second spacer layer has a first U-shape cross-section in a cross-sectional view along the isolation structures, etching back the second spacer layer is performed such that the second spacer layer is changed from the first U-shape cross-section to a rectangular cross-section in the cross-sectional view along the isolation structures, and etching the first, second, and third spacer layers and the semiconductor fin to form recesses is performed such that the second spacer layer is changed from the rectangular cross-section to a second U-shape cross-section.

In some embodiments, the first, second, and third spacer layers are made of different dielectric materials.

In some embodiments of the present disclosure, a method includes forming first and second semiconductor fins over the substrate; forming isolation structures laterally surrounding the semiconductor fin; forming a gate structure over the semiconductor fin; forming a first spacer layer and a second spacer layer over the gate structure and the first and second semiconductor fins; etching back the second spacer layer to remove portions of the second spacer layer outside a space laterally between the first and second semiconductor fins, wherein a remaining portion of the second spacer layer is laterally between the first and second semiconductor fins; etching the first and second spacer layers and the first and second semiconductor fins to form recesses; and forming epitaxial source/drain structures in the recesses.

In some embodiments, the method further includes after etching back the second spacer layer, forming a third spacer layer over and in contact with the first and second spacer layers.

In some embodiments, the method further includes etching back the third spacer layer to expose sidewall of the first spacer layer.

In some embodiments, the method further includes forming a contact etch stop layer over the epitaxial source/drain structures, wherein the contact etch stop layer is in contact with a sidewall of the first spacer layer; and forming an interlayer dielectric layer over the contact etch stop layer.

In some embodiments, the contact etch stop layer is separated from the remaining portion of the second spacer layer.

In some embodiments, the second spacer layer is thicker than the first spacer layer.

In some embodiments, forming the first spacer layer and the second spacer layer is performed such that an entirety of the space laterally between the first and second semiconductor fins is filled with the first spacer layer and the second spacer layer.

In some embodiments of the present disclosure, a device includes a substrate having a semiconductor fin, isolation structures over the substrate and laterally surrounding the semiconductor fin, a gate structure over the semiconductor fin, a gate spacer on a sidewall of the gate structure, and epitaxial source/drain structures on opposite sides of the gate structure. The gate spacer includes a first spacer layer, a second spacer layer over the first spacer layer, and a third spacer layer over the second spacer layer, in which in a first cross-sectional view along the isolation structures, a top surface of the second spacer layer is lower than a top surface of the third spacer layer, and the top surface of the third spacer layer is lower than a top surface of the first spacer layer.

In some embodiments, the device further includes a contact etch stop layer over the epitaxial source/drain structures, wherein in the first cross-sectional view, the contact etch stop layer is in contact with the first spacer layer and the third spacer layer.

In some embodiments, in the first cross-sectional view, a gap is vertically between one of the epitaxial source/drain structures and the second spacer layer of the gate spacer.

In some embodiments, in a second cross-sectional view along the semiconductor fin, the top surface of the third spacer layer is lower than a top surface of one of the source/drain structures.

In some embodiments, a dielectric constant of the second spacer layer is lower than dielectric constants of the first and third spacer layers.

In some embodiments, in the first cross-sectional view, one of the epitaxial source/drain structures is in contact with the second and third spacer layers and is separated from the first spacer layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a semiconductor fin over a substrate;
forming isolation structures laterally surrounding the semiconductor fin;
forming a gate structure over the semiconductor fin;
forming a first spacer layer and a second spacer layer over the gate structure and the semiconductor fin;
etching back the second spacer layer, such that a top surface of the second spacer layer is lower than a top surface of the first spacer layer;
after etching back the second spacer layer, forming a third spacer layer over the first spacer layer and the second spacer layer;
etching the first, second, and third spacer layers and the semiconductor fin to form recesses; and
forming epitaxial source/drain structures in the recesses.

2. The method of claim 1, further comprising etching back the third spacer layer to expose sidewall of the first spacer layer after forming the epitaxial source/drain structures in the recesses.

3. The method of claim 2, wherein etching back the third spacer layer is performed such that a top surface of the third spacer layer is lower than a topmost end of one of the epitaxial source/drain structures.

4. The method of claim 2, further comprising forming a contact etch stop layer over the epitaxial source/drain structures, wherein the contact etch stop layer is in contact with the first and third spacer layers.

5. The method of claim 4, wherein the contact etch stop layer is separated from the second spacer layer by the third spacer layer.

6. The method of claim 1, wherein,
forming the second spacer layer is performed such that the second spacer layer has a first U-shape cross-section in a cross-sectional view along the isolation structures,
etching back the second spacer layer is performed such that the second spacer layer is changed from the first U-shape cross-section to a rectangular cross-section in the cross-sectional view along the isolation structures, and
etching the first, second, and third spacer layers and the semiconductor fin to form recesses is performed such that the second spacer layer is changed from the rectangular cross-section to a second U-shape cross-section.

7. The method of claim 1, wherein the first, second, and third spacer layers are made of different dielectric materials.

8. A method, comprising:
forming first and second semiconductor fins over the substrate;
forming isolation structures laterally surrounding the first and second semiconductor fins;
forming a gate structure over the semiconductor fin;
forming a first spacer layer and a second spacer layer over the gate structure and the first and second semiconductor fins;
etching back the second spacer layer to remove portions of the second spacer layer outside a space laterally between the first and second semiconductor fins, wherein a remaining portion of the second spacer layer is laterally between the first and second semiconductor fins;
etching the first and second spacer layers and the first and second semiconductor fins to form recesses; and
forming epitaxial source/drain structures in the recesses.

9. The method of claim 8, further comprising after etching back the second spacer layer, forming a third spacer layer over and in contact with the first and second spacer layers.

10. The method of claim 9, further comprising etching back the third spacer layer to expose sidewall of the first spacer layer.

11. The method of claim 8, further comprising:
forming a contact etch stop layer over the epitaxial source/drain structures, wherein the contact etch stop layer is in contact with a sidewall of the first spacer layer; and
forming an interlayer dielectric layer over the contact etch stop layer.

12. The method of claim 11, wherein the contact etch stop layer is separated from the remaining portion of the second spacer layer.

13. The method of claim 8, wherein the second spacer layer is thicker than the first spacer layer.

14. The method of claim 8, wherein forming the first spacer layer and the second spacer layer is performed such that an entirety of the space laterally between the first and second semiconductor fins is filled with the first spacer layer and the second spacer layer.

15. A device, comprising:
a substrate having a semiconductor fin;
isolation structures over the substrate and laterally surrounding the semiconductor fin;
a gate structure over the semiconductor fin;
a gate spacer on a sidewall of the gate structure, wherein the gate spacer comprises:
a first spacer layer;
a second spacer layer over the first spacer layer; and
a third spacer layer over the second spacer layer, wherein in a first cross-sectional view along the isolation structures, a top surface of the second spacer layer is lower than a top surface of the third spacer layer, and the top surface of the third spacer layer is lower than a top surface of the first spacer layer; and epitaxial source/drain structures on opposite sides of the gate structure.

16. The device of claim 15, further comprising a contact etch stop layer over the epitaxial source/drain structures, wherein in the first cross-sectional view, the contact etch stop layer is in contact with the first spacer layer and the third spacer layer.

17. The device of claim 15, wherein in the first cross-sectional view, a gap is vertically between one of the epitaxial source/drain structures and the second spacer layer of the gate spacer.

18. The device of claim 15, wherein in a second cross-sectional view along the semiconductor fin, the top surface of the third spacer layer is lower than a top surface of one of the source/drain structures.

19. The device of claim 15, wherein a dielectric constant of the second spacer layer is lower than dielectric constants of the first and third spacer layers.

20. The device of claim 15, wherein in the first cross-sectional view, one of the epitaxial source/drain structures is in contact with the second and third spacer layers and is separated from the first spacer layer.
